(19) United States
(12) Patent Application Publication
(10) Pub. No.: US 2011/0284069 A1
(43) Pub. Date: Nov. 24, 2011

(54) SOLAR CELL AND METHOD FOR MANUFACTURING THE SAME

(76) Inventors: Jinah KIM, Seoul (KR); Seunghwan Shim, Seoul (KR); Hyungjin Kwon, Seoul (KR); Juhong Yang, Seoul (KR); Ilhyoung Jung, Seoul (KR); Jeongbeom Nam, Seoul (KR)

(21) Appl. No.: 13/110,768

(22) Filed: May 18, 2011

(30) Foreign Application Priority Data
May 19, 2010 (KR) 10-2010-0046834

(51) Int. Cl. H01L 31/02; H01L 31/18; H01L 31/0236

(52) U.S. Cl. 136/256; 438/72; 257/E31.001

(57) ABSTRACT

A solar cell is discussed. The solar cell includes an anti-reflection unit positioned on an emitter unit and including a first anti-reflection film having a first refractive index and a second anti-reflection film having a second refractive index different from the first refractive index, wherein a plurality of depressions are formed on at least one surface of a substrate, a depth of each of the plurality of depressions is ⅓ to 1 times a distance between centers of at least two immediately adjacent depressions, and a width of each of the plurality of depressions is 1 to 3 times the depth of each of the plurality of depressions.

### CROSS-REFERENCE TO RELATED APPLICATION

This application claims priority to and the benefit of Korean Patent Application No. 10-2010-0046834 filed in the Korean Intellectual Property Office on May 19, 2010, the entire contents of which are incorporated herein by reference.

### BACKGROUND OF THE INVENTION

(a) Field of the Invention

Embodiments of the invention relate to a solar cell and a method for manufacturing the solar cell.

(b) Description of the Related Art

A silicon solar cell generally includes a substrate and an emitter unit, each of which is formed of a semiconductor, and a plurality of electrodes respectively formed on the substrate and the emitter unit. The semiconductors forming the substrate and the emitter unit have different conductive types, such as a p-type and an n-type. A p-n junction is formed at an interface between the substrate and the emitter unit.

When light is incident on the solar cell, a plurality of electron-hole pairs are generated in the semiconductors. The electron-hole pairs are separated into electrons and holes by the photovoltaic effect. Thus, the separated electrons move to the n-type semiconductor (e.g., the emitter unit) and the separated holes move to the p-type semiconductor (e.g., the substrate). The electrons and holes are respectively collected by the electrode electrically connected to the emitter unit and the electrode electrically connected to the substrate. The electrodes are connected to one another using electric wires to thereby obtain electric power.

### SUMMARY OF THE INVENTION

According to an aspect of the invention, there is provided a solar cell including a substrate having a first conductive type; an emitter unit having a second conductive type, which is the opposite of the first conductive type, and forming a p-n junction with the substrate; an anti-reflection unit positioned on the emitter unit and including a first anti-reflection film having a first refractive index and a second anti-reflection film having a second refractive index different from the first refractive index; a first electrode connected to the emitter unit; and a second electrode connected to the substrate, wherein a plurality of depressions are formed on at least one surface of the substrate, a depth of each of the plurality of depressions is ⅓ to 1 times a distance between centers of at least two immediately adjacent depressions, and a width of each of the plurality of depressions is 1 to 3 times the depth of each of the plurality of depressions.

The plurality of depressions are formed such that their centers may be aligned in a column direction and in a row direction.

The plurality of depressions are formed such that their centers may not be aligned in at least one of the column direction and the row direction.

The depth of each of the plurality of depressions may range from 10 μm to 70 μm.

The distance between the centers of the at least two immediately adjacent depressions may range from 30 μm to 70 μm.

The width of each of the plurality of depressions ranges from 30 μm to 70 μm.

A planar shape of each of the plurality of depressions may be one of a circular shape, an oval shape, and a polygonal shape.

A sectional shape of each of the plurality of depressions may be one of a semi-circular shape and a semi-oval shape.

The first anti-reflection film may be made of the same material as that of the second anti-reflection film.

The same material may be silicon nitride.

The first refractive index may be greater than the second refractive index.

The first refractive index may range from 2.3 to 2.9, and the second refractive index may range from 1.7 to 2.2.

According to another aspect of the invention, there is provided a method for fabricating a solar cell, including forming a plurality of depressions by irradiating a laser to a substrate having a first conductive type before removing saw damage caused during a previous cutting of the substrate; simultaneously removing the saw damage and damage caused by laser irradiation by performing wet etching using an etchant after the laser irradiation; forming an emitter unit of a second conductive type, which is the opposite of the first conductive type, on the substrate with the plurality of depressions formed thereon; and forming a first electrode electrically connected to the emitter unit and a second electrode electrically connected to the substrate.

The plurality of depressions may be formed such that the depth of each of the plurality of depressions is ⅓ to 1 times the distance between the centers of the at least two immediately adjacent depressions.

The plurality of depressions may be formed such that the width of each of the plurality of depressions is 1 to 3 times the depth of each of the plurality of depressions.

In performing wet etching, any one of a nitric acid, a hydrofluoric acid, an acetic acid, and a mixture solution thereof may be used as an etchant.

The thickness of a portion removed by the wet etching may range from 3 μm to 5.5 μm.

The forming of the plurality of depressions may include: performing linear laser processing in a first direction; and performing linear laser processing in a second direction different from the first direction, wherein the plurality of depressions are formed at crossings of regions where a laser has been irradiated in the first direction and regions where the laser has been irradiated in the second direction.

The second direction may be perpendicular to the first direction.

The second direction may cross the first direction at an angle ranging from 40° to 80°.

In forming the plurality of depressions, the plurality of depressions may be formed through a spot laser processing.

In forming the plurality of depressions, the depth of each of the plurality of depressions and the distance between the centers of the at least two adjacent depressions may be adjusted by adjusting at least one of a speed and a frequency of the laser.

The substrate may be a polycrystalline silicon substrate.

The method may further include forming an anti-reflection unit by forming a first anti-reflection film having a first refractive index on the emitter unit and forming a second anti-reflection film having a second refractive index on the first anti-reflection film, the second refractive index being smaller than the first refractive index.

The first refractive index may range from 2.3 to 2.9, and the second refractive index may range from 1.7 to 2.2.

The first anti-reflection film and the second anti-reflection film may be made of the same material.

The first anti-reflection film and the second anti-reflection film may be formed of silicon nitride.

In forming the anti-reflection unit, the first and second anti-reflection films may be formed in a single chamber.

The forming of the first and second electrodes may include: printing a first paste on the anti-reflection unit to form a first electrode pattern; printing a second paste on the substrate to form a second electrode pattern; and thermally treating the substrate having the first and second electrode patterns to form the respective first and second electrodes. The method may further include forming a second electric field unit on the substrate in contact with the second electrode when the substrate is thermally treated.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 illustrates a partial perspective view of a solar cell according to an embodiment of the invention;

FIG. 2 illustrates a cross-sectional view of a solar cell cut along the II-II line shown in FIG. 1;

FIGS. 3A and 3B illustrate portions of textured surfaces according to embodiments of the invention;

FIG. 4 illustrates various examples of depressions according to embodiments of the invention;

FIGS. 5A to 5F are cross-sectional views sequentially illustrating a method for manufacturing the solar cell shown in FIG. 1;

FIG. 6 is a graph showing reflectance of light with respect to wavelength of light after performing texturing but before forming an anti-reflection unit according to a comparative example and an embodiment of the invention;

FIG. 7 is a graph showing reflectance of light with respect to wavelength of light after performing texturing and after forming first and second anti-reflection films according to a comparative example and an embodiment of the invention;

FIGS. 8A and 8B illustrate laser texturing methods according to embodiments of the invention.

### DETAILED DESCRIPTION OF THE EMBODIMENTS

Embodiments of the invention will be described more fully hereinafter with reference to the accompanying drawings, in which example embodiments of the inventions are shown. This invention may, however, be embodied in many different forms and should not be construed as limited to only the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

Hereinafter, according to the invention, example embodiments of a solar cell will be described with reference to appended drawings.

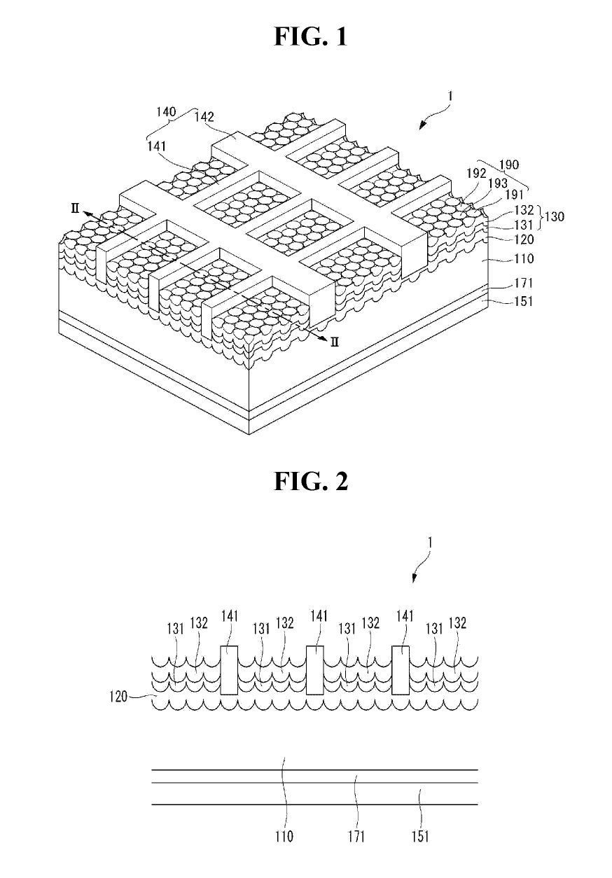

First, a solar cell according to an embodiment of the invention will now be described with reference to FIGS. 1 to 4.

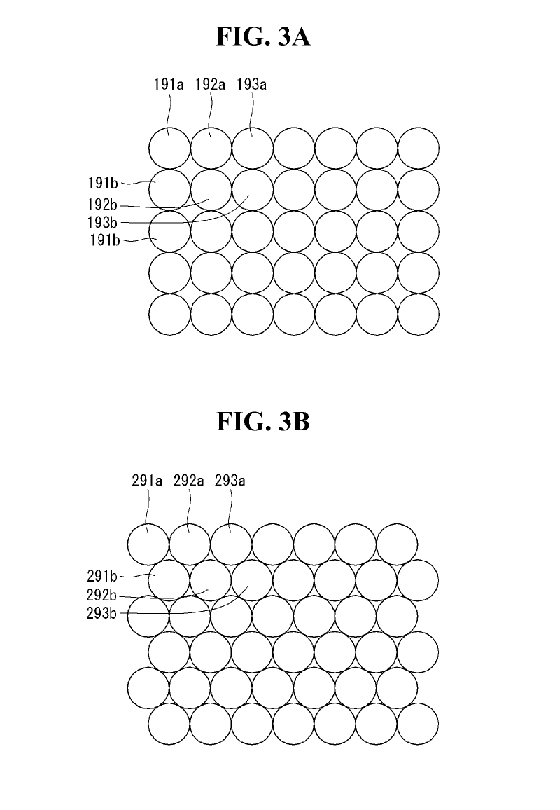

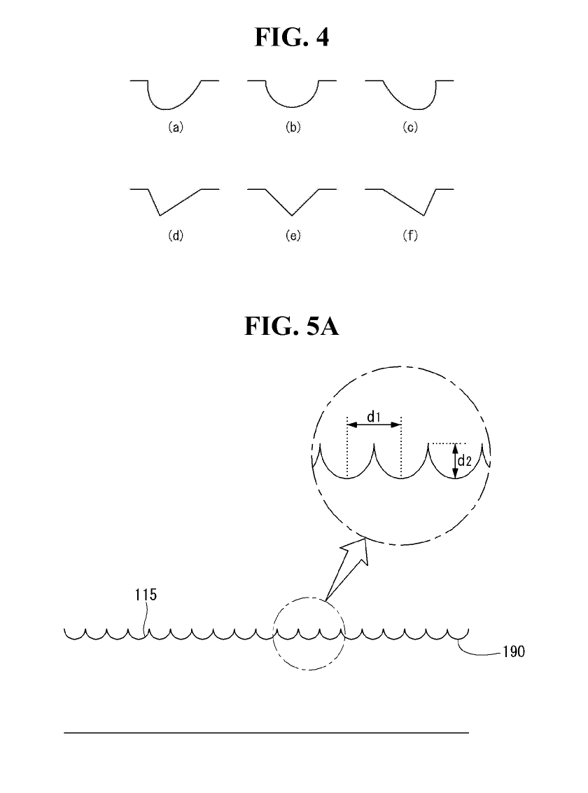

FIG. 1 illustrates a partial perspective view of a solar cell according to an embodiment of the invention. FIG. 2 is a cross-sectional view of the solar cell taken along line II-II in FIG. 1. FIGS. 3A and 3B illustrate portions of textured surfaces according to embodiments of the invention. FIG. 4 illustrates various examples of sectional shapes of a plurality of depressions according to embodiments of the invention.

Referring to FIG. 1, a solar cell 1 according to an embodiment of the invention includes a substrate 110, an emitter unit 120 disposed on a surface of the substrate 110 on which light is incident (hereinafter, it is referred to as a ‘front surface’), an anti-reflection layer 130 disposed on the emitter unit 120, a front electrode unit 140 connected to the emitter unit 120, a rear electrode 151 on a surface of the substrate 110, the surface being one that is opposite the front surface and without incident light (hereinafter, it is referred to as a ‘rear surface’), and a back surface field (BSF) region 171 disposed at the rear surface of the substrate 110. The back surface field (BSF) region 171 may be disposed at a location between the substrate 110 and the rear electrode 151.

A substrate 110 is a semiconductor substrate made from a material, such as silicon of a first conductive type, for example, p-type conductive silicon. In this instance, polycrystalline silicon is used, however, single crystal silicon or amorphous silicon may also be used.

In the embodiment, since the substrate 110 has a p-type conductive type, the substrate 110 may have an impurity of a group III element such as boron (B), gallium (Ga), and indium (In).

However, differently from the above, the substrate 110 may have an n-type conductive type. In this instance, the substrate 110 may have an impurity of a group V element such as phosphorus (P), arsenic (As), and antimony (Sb). Also, in an alternative embodiment, the substrate 110 may also be made from semiconductor materials other than silicon.

The substrate may be fabricated through a smelting process (i.e., a melt method or a fusion method). Namely, silicon raw material, such as a silica (SiO₂) material, and a reactive material, a metal material, are melted together in a furnace to remove impurities from the raw material, thus fabricating the substrate 110. The substrate 110 may be a polycrystalline silicon substrate having a purity level of 5N or lower, and preferably, though not required, a polycrystalline silicon substrate having a purity level ranging from 2N to 5N. In this instance, the purity level of 5N of the substrate 100 refers to a content of silicon (Si) of the substrate 110 being 99.999% (five 9s) or greater. In other words, the purity level of 5N of the substrate 110 refers to the content of silicon (Si) of the substrate 110 being a class of 99.999%. As the metal material, aluminum (Al) is used, so the substrate 110 includes impurities of a metal material such as aluminum (Al) or impurities of iron. Thus, the content or concentration of the impurities of the metal material contained in the substrate 110 may range from 0.001 to 1.0 ppmw, and in this instance, the amount of aluminum (Al) contained in the substrate 110 may range from 0.01 to 0.8 ppmw and the amount of iron (Fe) contained in the substrate 110 may range from 0.01 to 1 ppmw.

In an instance of using the substrate 110 fabricated through the smelting method to have low purity level due to the high impurity concentration, when compared with a substrate fabricated through chemical vapor deposition (CVD), a method for generating silicon (Si) gas by vaporizing silicon (Si) and collecting the generated silicon (Si) gas to grow crystal, the fabrication unit cost of the substrate 110 can be lowered to reduce the fabrication unit cost of the solar cell 1. However, the efficiency of the solar cell 1 is lower than that of the solar cell using the substrate fabricated through CVD. Thus, in order to compensate for this, a bulk life time of minority carrier in the substrate 110 fabricated through the smelting method is about 0.1 μs to 2 μs. In this instance, the bulk life time refers to duration from a point in time at which carrier is generated in the substrate by incident light to a point in time at which the generated carrier becomes extinct, namely, a bulk life time of the substrate 110 in a silicon wafer state. When the bulk life time is about 0.1 μs or shorter, a time for a front electrode unit 140 and the rear electrode 151 to collect electrons and holes is short, lowering the efficiency of the solar cell 1.

The bulk life time differs according to whether or not the substrate 110 is subjected to chemical passivation processing. Namely, when the chemical passivation processing is performed on the substrate 110, the bulk life time is lengthened. For example, when the chemical passivation processing is performed on the substrate 110, the bulk life time of the substrate 110 may be about 5 μs or longer, and preferably, though not required, when the substrate 110 fabricated through the smelting method is subjected to the chemical passivation processing, the bulk life time of the substrate 110 may ranging from 5 μs to 15 μs. Also, when the substrate 110 fabricated through the smelting method is employed, if the content of boron (B) is too small, the amount of carrier generated in the substrate 110 would be so small that the efficiency of the solar cell may be degraded, and conversely, if the content of boron (B) is too great, the total content of impurities would be overly increased to degrade the efficiency of the solar cell 1.

Thus, in order to prevent the degradation of efficiency of the solar cell 1 fabricated through the smelting method, the concentration of boron (B) is about 3×10¹⁶ atoms/cm³ to 8×10¹⁶ atoms/cm³. The concentration of phosphor (P) in this instance may be about 9×10¹⁶ atoms/cm³ to 4.5×10¹⁶ atoms/cm³. Also, oxygen and carbon contained in the substrate 110 can improve electrical characteristics of the substrate 110. However, if the content of oxygen and carbon is too high, oxygen and carbon would act as impurities to negatively affect the generation of carrier to result in shortening the bulk life time. Thus, the oxygen concentration of the substrate 110 may be about 1×10¹⁷ atoms/cm³ to 1×10¹⁹ atoms/cm³ and the carbon concentration of the substrate 110 may be about 1×10¹⁶ atoms/cm³ to 1×10¹⁹ atoms/cm³. Also, in an alternative embodiment, the substrate 110 may be a metallurgical grade silicon substrate, such as a silicon substrate having a purity level ranging from 2N to 5N.

Such a substrate 110 is textured to have a textured surface having a plurality of depressions 190. As for the ratio between a depth d2 of each of the plurality of depressions and a distance d1 between centers of mutually adjacent depressions 190, the depth d2 ranges from ⅓ to 1 of the distance d1. The width of each of the plurality of depressions 190 ranges from 1 to 3 times the depth of the depressions 190.

If the depth d2 of each of the plurality of depressions 190 is smaller than ⅓ of the distance d1 between the centers of mutually adjacent depressions 190, a light receiving area of the substrate 110 would be reduced and a reflection reducing or preventing effect aimed to be achieved by the texturing would deteriorate, and in the case of the polycrystalline silicon substrate, after a plurality of depressions 190 are formed by irradiating a laser, and when saw damage and laser damage are simultaneously removed through wet etching, the textured structure can be hardly maintained or persevered.

Meanwhile, if the depth d2 of each of the plurality of depressions is greater than 1 times the distance d1 between the centers of mutually adjacent depressions 190, even when the saw damage and the laser damage are simultaneously removed through wet etching, the textured structure can be easily maintained or preserved. However, in order to form the depressions 190 in the corresponding ratio on the polycrystalline substrate by using a laser, a laser irradiation time or duration must be lengthened or the intensity of a laser beam must be strong, which inevitably increase a damage generation area by the laser to thereby reduce the efficiency of the solar cell.

Thus, when the depth d2 of each of the plurality of depressions is ⅓ to 1 times the distance d1 between the centers of mutually adjacent depressions 190, although the saw damage and laser damage are simultaneously removed through wet etching, the textured structure of the polycrystalline silicon substrate can be maintained or preserved, and the reflectance of light made incident to the substrate 110 can be effectively reduced.

Similarly, when the width of each of the plurality of the depressions 190 ranges from 1 to 3 times (i.e., 1× to 3×) the depth of the depressions 190, although the saw damage and laser damage are simultaneously removed through wet etching in a follow-up step of the laser processing (Le., laser beam machining, or laser machining), the textured surface can be maintained or maintained, and also the surface reflectance can be reduced.

In an embodiment of the invention, the depth d2 of each of depressions 190 (such as two mutually adjacent depressions 190) ranges from 10 μm to 70 μm, and preferably, though not required, ranges from 30 μm to 70 μm. The distance d1 between the centers of the two mutually adjacent depressions 190 ranges from 30 μm to 70 μm, and the width of each of the two mutually adjacent depressions 190 ranges from 30 μm to 70 μm.

If the depth d2 of each of the depressions 190 is 10 μm or greater, although the saw damage and laser damage are simultaneously removed through wet etching in the follow-up step of the laser processing, the textured surface can be maintained or preserved to reduce a surface reflectance. When the depth d2 of each of the depressions 190 is 70 μm or smaller, the thickness of the emitter unit 120 can be stably secured to ensure a stable p-n junction. When the depressions 190 having the foregoing depth are formed by using a laser, a reduction in the efficiency of the solar cell 1 due to damage caused by the laser can be prevented or reduced.

When the distance d1 between the centers of the mutually adjacent depressions ranges from 30 μm to 70 μm, although the saw damage and laser damage are simultaneously removed through wet etching in the follow-up step of the laser processing, the textured surface can be maintained or preserved to reduce a surface reflectance. Also, when the width of each of the depressions 190 (including the mutually adjacent depressions) ranges from 30 μm to 70 μm, although the saw damage and laser damage are simultaneously removed through wet etching in the follow-up step of the laser processing, the textured surface can be maintained to reduce a surface reflectance.

In the example embodiment, as illustrated in FIG. 3A, the plurality of depressions ([191a,192a,193a] and [191b, 192b, 192c] are formed at regular intervals in a column direction. The regular interval refers to the distance between the centers of two adjacent depressions being regular. The column direction in FIGS. 1 to 3 is substantially parallel to a direction crossing the direction in which the front electrode 141 is formed, but the embodiment of invention is not limited thereto.

In FIG. 3A, the centers of the plurality of depressions 190 are consistent or aligned in the column direction and in a row direction. In other words, the centers of the two adjacent depressions 191a and 192a adjacent in the row direction are on the same line or aligned in the row direction, and the centers of two depressions 191a and 191b adjacent in the column direction crossing the row direction are positioned on the same line or aligned in the column direction. In an embodiment of the invention, the column direction and the row direction may be perpendicular.

Through the texturing, the reflectance of the surface of the solar cell 1 can be effectively reduced, and since the plurality of depressions 190 are formed at the crossings through a linear laser processing in the column and row directions, the fabrication process is simple. Additionally, the lines in the row direction and the lines in the column direction may each be straight, whereby the centers of the plurality of depressions 190 are aligned along the straight lines.

Alternatively, the plurality of depressions may be formed such that the centers thereof are not consistent in at least one of the column and row directions. As shown in FIG. 3B, the plurality of depressions ([291a, 292a, 293a] and [291b, 292b, 293b]) are also formed at regular intervals in the row direction. For example, the two depressions 291a and 292a adjacent in the row direction may be positioned such that centers thereof are on the same line in the row direction. On the other hand, the two depressions 291a and 291b adjacent in the column direction may be positioned such that the centers thereof are not on the same line in the column direction that is perpendicular to the row direction. Nevertheless, the two depressions 291a and 291b that are adjacent may be positioned such that the centers of the depressions 291a and 291b are on a same line that is angled from the line in the row direction, and the angle between such two lines may be 25° to 80°, for example, 40° to 80°. Accordingly, in another embodiment of the invention, the column direction and the row direction need not be perpendicular.

As shown in FIG. 4, the plurality depressions 190 may have various shapes of sections. In order to increase a light receiving area, a semi-circular or a semi-oval shape as shown in (a), (b), and (c) of FIG. 4 is preferred, but not required. Alternatively, the sections of the plurality of depressions 190 may have a horn-like shape, or a sharp recess, as shown in (d), (e), and (f) of FIG. 4. Also, as shown in (a), (c), (d), and (f) of FIG. 4, the depressions 190 may be formed to have a different angle with respect to the substrate 110. The shapes of the sections of the plurality of depressions 190 may be variably changed, respectively, in order to reduce the reflectance of light made incident to the substrate 110 and improve the efficiency of the solar cell 1.

A planar shape of each of the depressions may be a circular shape as shown, but embodiments of the invention are not limited thereto. Namely, the planar shape of each of the depressions may be an oval shape, a polygonal shape, or an irregular shape, or a combination thereof.

The plurality of depressions 190 may not be formed on a region of the substrate 110 immediately under the front electrode unit 140. Namely, the region, where the front electrode unit 140 is to be formed, is not textured so as to have a flat surface, rather than an irregular surface, thereby improving contact characteristics between the front electrode unit 140 and the emitter unit 120.

Thus, when the polycrystalline silicon substrate is laser-processed by the textured surface having the plurality of depressions 190 according to an embodiment of the invention, although the saw damage and laser damage are simultaneously removed through wet etching, the textured surface can be substantially maintained or preserved as it is, a light receiving area of the substrate 110 can be increased, and the reflectance of light made incident to the substrate 110 can be reduced, thus improving the efficiency of the solar cell 1.

The emitter unit 120 formed on the substrate 110 is an impurity region equipped or doped with a second conductive type such as an n-type, which is the opposite of a conductive type of the substrate 110, and forms a p-n junction with the substrate 110.

By a built-in potential difference generated due to the p-n junction, a plurality of electron-hole pairs, which are generated by incident light onto the semiconductor substrate 110, are separated into electrons and holes, respectively, and the separated electrons move toward the n-type semiconductor and the separated holes move toward the p-type semiconductor. Thus, when the substrate 110 is of the p-type and the emitter unit 120 is of the n-type, the separated holes move toward the substrate 110 and the separated electrons move toward the emitter unit 120.

Because the emitter unit 120 forms the p-n junction with the substrate 110, when the substrate 110 is of the n-type, then the emitter unit 120 is of the p-type, in contrast to the embodiment discussed above, and the separated electrons move toward the substrate 110 and the separated holes move toward the emitter unit 120.

Returning to the embodiment when the emitter unit 120 is of the n-type, the emitter unit 120 may be formed by doping the substrate 110 with impurities of the group V element, while when the emitter unit 120 is of the p-type, the emitter unit 120 may be formed by doping the substrate 110 with impurities of the group III element.

The anti-reflection unit 130 includes a first anti-reflection film 131 positioned on the emitter part 120 and a second anti-reflection film 132 positioned on the first anti-reflection film 131. The total thickness of the anti-reflection unit 130 ranges from 80 nm to 120 nm.

The first anti-reflection film 131 may be formed of a silicon nitride film (SiNx), may have a thickness ranging from 30 nm to 50 nm, and may have a refractive index ranging from 2.3 to 2.9.

The first anti-reflection film 131 exhibiting a passivation effect whereby a defect such as a dangling bond existing on the surface of the substrate 110 are stabilized, reduces charges that move to the emitter unit 120 from being recombined with unstable bonds, and also reduces the reflectance of light made incident to the substrate 110.

If the refractive index of the first anti-reflection film 131 is less than a lower limit (i.e., about 2.3), the first anti-reflection film 131 allows light to be easily reflected so as to fail to properly serve as an anti-reflection film, and the passivation effect is degraded to reduce the efficiency of the solar cell 1. Conversely, if the refractive index of the first anti-reflection film 131 exceeds an upper limit (i.e., about 2.9), the first anti-reflection film 131 itself absorbs incident light so as to reduce the quantity of light reaching the substrate 110 to result in a reduction in photoelectric efficiency.

Also, if the thickness of the first anti-reflection film 131 is smaller than a lower limit (i.e., about 30 nm), the first anti-reflection film 131 may not properly perform its function. Further, if the thickness of the first anti-reflection film 131 exceeds an upper limit (i.e., 50 nm), the quantity of light absorbed to the first anti-reflection film 131 increases, and the unnecessary increase in the thickness of the first anti-reflection film 131 leads to an increase in the fabrication cost and lengthening of a processing time of the solar cell 1.

The second anti-reflection film 132 exists only on the first anti-reflection film 131, may be formed of a silicon nitride film like the first anti-reflection film 131, may have a thickness ranging from 50 nm to 70 nm, and may have a refractive index ranging from 1.7 to 2.2.

Such a second anti-reflection film 132, together with the first anti-reflection film 131, reduces the reflectance of light made incident to the substrate 110, increasing the quantity of light absorbed in to the substrate 110. Also, by virtue of hydrogen included in the silicon nitride film (SiNx) of the second anti-reflection film 132, the second anti-reflection film 132, together with the first anti-reflection film 131, further improves the passivation effect with respect to the unstable bonds. As afore-mentioned, the reflective index of the second anti-reflection film 132 is smaller than that of the first anti-reflection film 131, and the second anti-reflection film 132 has an improved anti-reflection function compared with the first anti-reflection film 131. In addition, a change in the refractive index from the first anti-reflection film 131 to the second anti-reflection film 132 is discontinuous. For example, the refractive index from the first anti-reflection film 131 to the second anti-reflection film 132 is discontinuously reduced.

If the refractive index of the second anti-reflection film 132 is less than a lower value (i.e., about 1.7), the second anti-reflection film 132 allows light to be easily reflected, failing to properly serve as an anti-reflection film. Also, if the refractive index of the second anti-reflection film 132 exceeds an upper limit (i.e., about 2.2), the second anti-reflection film 132 itself absorbs incident light, reducing the photoelectric efficiency of the substrate 110.

In addition, if the thickness of the second anti-reflection film 132 is smaller than a lower limit (i.e., about 50 nm), the second anti-reflection film 132 could not properly perform the anti-reflection function, and if the thickness of the second anti-reflection film 132 exceeds an upper limit (i.e., 70 nm), the second anti-reflection film 132 absorbs light.

In embodiments of the invention, the first anti-reflection film 131 is thinner than or equal to the second anti-reflection film 132. Similarly, the second anti-reflection film 132 is greater than or equal to the first anti-reflection film 131. In other embodiments of the invention, the refractive index of the first anti-reflection film 131 and/or the second anti-reflection film 132 may depend on the thickness of the respective first and second anti-reflection films 131 and 132. For example, the refractive index of the first anti-reflection film 131 may be inversely proportional to its thickness, and the refractive index of the second anti-reflection film 132 maybe inversely proportional to its thickness.

The anti-reflection unit 130 has a dual-film structure, but alternatively, the anti-reflection unit 130 may have a single film structure or a multi-layered film structure. Alternatively, the anti-reflection unit 130 may be omitted as necessary or desired. In this embodiment of the invention, anti-reflection layer 130 has a double -layered structure, but a single -layered or a multi-layered structure may also be employed, and in some instances, the anti-reflection layer 130 may be removed depending on the need or desire.

The front electrode unit 140, as shown in FIGS. 1 and 2, includes a plurality of first electrodes 141 and a plurality of charge collectors 142 (hereinafter, referred to as ‘a plurality of first electrode charge collectors 142) for the first electrodes 141.

The plurality of first electrodes 141 are electrically and physically connected to the emitter unit 120 and extend in a predetermined direction nearly in parallel to each other.

The plurality of first electrodes 141 collect charges, e.g., electrons that move to the emitter unit 120.

The plurality of first electrode charge collectors 142 extend in a direction intersecting the first electrodes 141, and are connected electrically and physically to the first electrodes 141 as well as the emitter unit 120.

The plurality of first electrode charge collectors 142 are disposed in the same layer as the plurality of first electrodes 141 and are connected to the corresponding first electrodes 141 electrically and physically at the crossing points with the respective first electrodes 141.

The plurality of first electrode charge collectors 142 described above collect charges transferred through the plurality of first electrodes 141 and output them to an external device.

The front electrode unit 140 contains a conductive material such as silver (Ag), may contain at least one selected from a group consisting of nickel (Ni), copper (Cu), aluminum (Al), tin (Sn), zinc (Zn), indium (In), titanium (Ti), gold (Au), and a combination thereof or other conductive materials different from the above.

Due to the front electrode unit 140 being connected electrically and physically to the emitter unit 120, the anti-reflection layer 130 is disposed on the emitter unit 120 where the front electrode unit 140 is not disposed.

The rear electrode 151 on the rear surface of the substrate 110 is positioned on almost the entire area of the rear surface of the substrate 110. The rear electrode 151 collects charges, such as holes, moving to the direction of the substrate 110.

The rear electrode 151 contains at least one conductive material such as aluminum (Al), but in an alternative embodiment, may contain at least one selected from a group consisting of nickel (Ni), copper (Cu), silver (Ag), tin (Sn), zinc (Zn), indium (In), titanium (Ti), gold (Au), and a combination thereof or other conductive materials different from the above.

The back surface field region 171 disposed between the rear electrode 151 and the substrate 110 is a region where impurities of the same conductive type as the substrate 110 are doped more heavily than the substrate 110, for example, p+ region.

A potential barrier is formed by an impurity density difference between the substrate 110 and the back surface field region 171, thereby distributing the movement of charges (for example, electrons) to a rear portion of the substrate 110. Accordingly, the back surface field region 171 prevents or reduces the recombination and/or the disappearance of the separated electrons and holes at the rear surface of the substrate 110.

In addition to the structure above, the solar cell 1 may further include a plurality of charge collectors (referred to as ‘a plurality of rear electrode charge collectors) for the rear electrode 151, which are disposed on the rear surface of the substrate 110.

The plurality of rear electrode charge collectors, similar to the plurality of first electrode charge collectors 142, are connected electrically to the rear electrode 151, and collect charges transferred from the rear electrode 151 and output them to the external device. The rear electrode charge contains at least one conductive material such as silver (Ag).

An operation of the solar cell 1 having the above desired structure will be described in detail.

When light irradiated to the solar cell 1 is incident on the substrate 110 through the anti-reflection layer 130 and the emitter unit 120, a plurality of electron-hole pairs are generated in the substrate 110 by light energy based on the incident light.

Further, since a reflection loss of light incident onto the substrate 110 is reduced by the anti-reflection layer 130, an amount of the incident light on the substrate 110 increases.

The electron-hole pairs are separated by the p-n junction of the substrate 110 and the emitter unit 120, and the separated electrons move toward the emitter unit 120 of the n-type and the separated holes move toward the substrate 110 of the p-type. The electrons that move toward the emitter unit 120 are collected by the front electrodes 141 in contact with the emitter portions 120 and then move to the first electrode collectors 142, while the holes that move toward the substrate 110 are collected by the rear electrode 151 through the back surface field region 171. When the front electrodes 141 and the rear electrode 151 are connected with electric wires, current flows therein to thereby enable use of the current for electric power.

In this instance, owing to the anti-reflection unit 130 comprised of the first anti-reflection film 131 largely having the passivation effect and the second anti-reflection film 132 largely having the anti-reflection function, the amount of a loss of charges is reduced and the amount of incident light increases to improve the efficiency of the solar cell 1.

A method for fabricating the solar cell 1 according to an embodiment of the invention will now be described with reference to FIGS. 1, 3A to 5F, 8A and 8B.

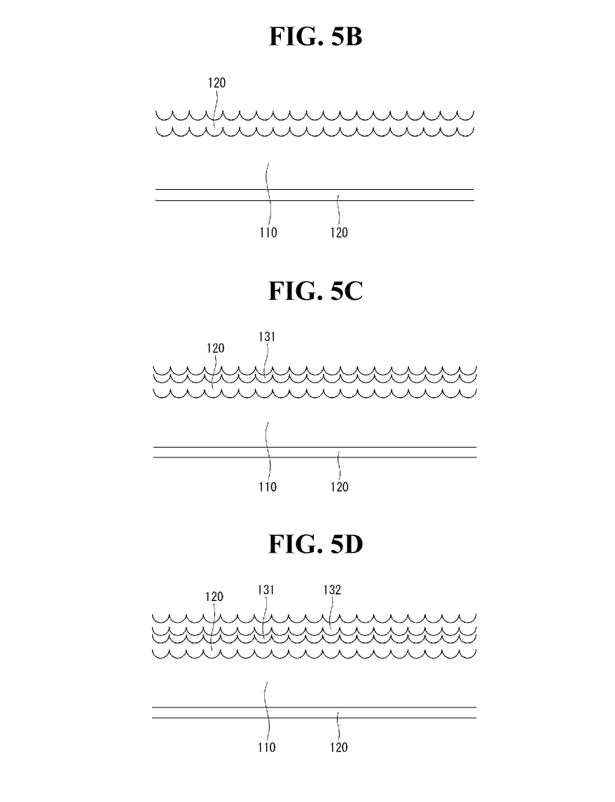

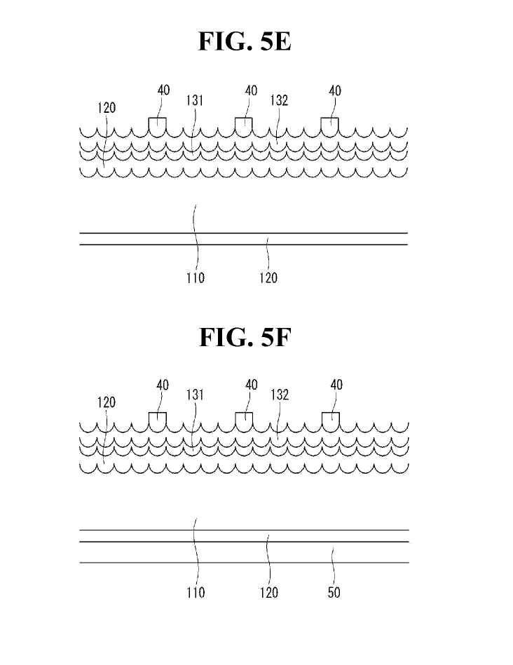

FIGS. 5A to 5F are sequential sectional views showing a method for fabricating a solar cell according to an embodiment of the invention, and FIGS. 8A and 8B sequentially show a laser texturing method according to an embodiment of the invention.

First, as shown in FIG. 5A, in order to perform etching to remove saw damage caused as the substrate 110 is cut, a laser is directly irradiated to the entire surface of the substrate 110 to form a textured surface 115 including a plurality of depressions 190. Namely, the surface of the substrate 110 is directly textured by using a laser beam irradiated from a laser irradiation device, without applying a mask. Thus, since a textured pattern having a desired size and shape is directly formed by controlling laser without applying a mask, the fabrication process is simple and a fabrication unit cost can be reduced. Also, the polycrystalline silicon substrate 110 can be textured to have a desired pattern without being dependent upon a crystallographic orientation and the size of grains of the polycrystalline silicon substrate 110.

The process of forming the plurality of depressions 190 will now be described in detail. First, as shown in FIG. 8A, primary linear laser processing is performed along a row direction. In an embodiment of the invention, laser beams are irradiated from left to right in odd numbered rows, and laser beams are irradiated from right to left in even numbered rows, but the invention is not limited thereto. Such laser beam irradiation direction need not be alternating. In another embodiment of the invention, the laser beam irradiation direction for each of the rows may be the same.

The process of formation of the plurality of depressions will now be described with reference to FIGS. 8A and 8B.

First, as shown in FIG. 8A, primary linear laser processing is performed along the row direction. In an embodiment of the invention, laser beams are irradiated from left to right in the odd numbered rows, and laser beams are irradiated from right to left in the even numbered rows, but the embodiment of the invention is not limited thereto.

Next, as shown in FIG. 8B, secondary linear laser processing is performed along a column direction substantially perpendicular to the row direction to form the plurality of depressions 190 at crossings of the regions in which laser has been irradiated in the row direction and the regions in which laser has been irradiated in the column direction. As for the textured surface formed through the laser processing, the centers of the plurality of depressions are consistent or aligned in the column direction and in the row direction as shown in FIG. 3A.

Alternatively, after the primary linear laser processing is performed along the row direction, secondary linear laser processing may be performed in a direction crossing at an angle ranging from 0° to 90° to the row direction to form the plurality of depressions 190 at the crossings. In this instance, the centers of the plurality of depressions 190 are consistent or aligned in the row direction, but inconsistent or not aligned in the column direction. Preferably, though not required, the secondary linear laser processing may be performed along a direction crossing at an angle ranging from 40° to 80° to the row direction to form the plurality of depressions 190.

When texturing is performed through the linear laser processing, the positions where the plurality of depressions 190 are to be formed can be adjusted by changing only the laser irradiation place or location, without having to change the laser pulse repetition frequency, so the laser texturing process can be simplified.

Unlike this embodiment of the invention, the surface may be textured through short laser processing in another embodiment. Namely, the depth of each of the depressions 190 can be adjusted by adjusting the speed of laser, and the distance between the centers of two adjacent depressions 190 can be adjusted by adjusting the frequency of the laser, for example, in terms of irradiation. Also, the depressions 190 may be formed to have different angles with respect to the substrate 110 by adjusting the irradiation direction (or irradiation angle) of the laser beam with respect to a surface of the substrate 110 to form the depressions 190 as shown in (a), (c), (d), and (f) of FIG. 4. Accordingly, one or more depressions 190 may be formed at an incline relative to the surface of the substrate 110. Alternatively, or in combination, the depressions 190 may be formed to be perpendicular with respect to the substrate 110 or the surface of the substrate 110 by adjusting the irradiation direction (or irradiation angle) of the laser beam with respect to a surface of the substrate 110 to be perpendicular so as to form the depressions 190 as shown in (b) and (e) FIG. 4.

When the surface is textured through the short laser processing, the positions where the plurality of depressions are to be formed must be adjusted by controlling the laser irradiation spots and the laser pulse repetition frequency, but the surface can be more elaborately processed or differently processed.

As for the ratio between the depth d2 of each of the plurality of depressions and the distance d1 between the centers of mutually adjacent depressions 190, the plurality of depressions 190 may be formed such that the depth d2 ranges from ⅓ to 1 times the distance d1, and the width of each of the plurality of depressions 190 ranges from 1 to 3 times the depth of the depressions 190.

Thus, when the plurality of depressions 190 are formed such that the depth d2 of each of the plurality of depressions 190 is ⅓ to 1 times the distance d1 between the centers of mutually adjacent depressions 190, although the saw damage and laser damage of the polycrystalline silicon substrate 110 are simultaneously removed through wet etching in a follow-up stage, the textured structure of the polycrystalline silicon substrate 110 can be maintained and the reflectance of light made incident to the substrate 110 can be effectively reduced.

Similarly, when the plurality of depressions 190 are formed such that the width of each of the plurality of the depressions 190 ranges from 1 to 3 times the depth of the depressions, although the saw damage and laser damage are simultaneously removed through wet etching in a follow-up step of the laser processing, the textured surface can be maintained or preserved and also the surface reflectance can be reduced.

In an embodiment of the invention, the depth d2 of each of mutually adjacent depressions 190 ranges from 10 μm to 70 μm, and preferably, though not required, ranges from 30 μm to 70 μm. The distance d1 between the centers of two depressions 190 ranges from 30 μm to 70 μm, and the width of each of the depressions 190 ranges from 30 μm to 70 μm.

If the depth d2 of each of the depressions 190 is 10 μm or greater, although the saw damage and laser damage are simultaneously removed through wet etching in the follow-up step of the laser processing, the textured surface can be maintained to reduce the surface reflectance, and when the depth d2 of each of the depressions 190 is 70 μm or smaller, the thickness of the emitter unit 120 can be stably secured to ensure a stable p-n junction, and a reduction in the efficiency of the solar cell 1 due to damage caused by laser can be effectively reduced or prevented.

Also, when the plurality of depressions are formed such that the distance d1 between the centers of the mutually adjacent depressions 190 ranges from 30 μm to 70 μm and the width of each of the depressions 190 ranges from 30 μm to 70 μm, although the saw damage and laser damage are simultaneously removed through wet etching, the textured surface can be maintained or preserved to reduce the surface reflectance.

In the process of forming the front electrode unit pattern 40 having a front electrode pattern part and an electrode charge collector pattern part by controlling the laser subsequently, the plurality of depressions 190 may not be formed on the region of the substrate 110 where the front electrode unit pattern 40 is to be formed.

Namely, the region of the substrate 110 immediately under where the front electrode unit 140 is to be formed is not textured so as to maintain a flat surface instead of having an irregular surface. Thus, when the front electrode unit 140 is formed in a follow-up stage, the contact characteristics between the front electrode unit 140 and the emitter unit 120 can be improved.

After the plurality of depressions 190 are textured by an irradiated laser beam, saw damage is removed through wet etching. In this instance, the saw damage formed in a sliding process for fabricating the substrate for the solar cell 1 in an ingot and laser damage occurring in the laser texturing process are simultaneously removed.

Namely, laser texturing is performed immediately on the substrate 110 with the saw damage to remove a portion of the saw damage, and then, the saw damage remaining after the laser texturing and damage caused by the laser texturing are wet-etched by using any one selected from the group consisting of a nitric acid, a hydrofluoric acid, an acetic acid, and a mixture thereof as an etchant. The portion removed by the wet etching has a thickness ranging from 3 μm to 5.5 μm.

When the thickness of the portion removed through etching is 3 μm or greater, the saw damage and the laser damage can be simultaneously removed, and when the thickness of the portion removed through wet etching is 5.5 μm or smaller, the textured surface reducing the reflectance of the surface of the substrate 110 can be maintained or preserved.

Since the saw damage can be simultaneously removed in the process of removing the laser damage, rather than performing an additional saw damage etching step, the fabrication process of the solar cell 1 can be simplified and the fabrication time can be shortened.

As shown in FIG. 5B, a material including impurities of a pentavalent elements such as phosphor (P), arsenic (As), antimony (Sb), and the like, is spread on the substrate 110 through a spreading method using POCl₃, H₃PO₄, or the like, to form the n type emitter unit 120 on the entire surfaces, e.g., the front surface, the rear surface, and the side surface of the substrate 110.

When the n type substrate 110 contains impurities of boron (B), the substrate 110 may contain boron (B) having the concentration ranging from 3×10¹⁶ atoms/cm³ to 5×10¹⁶ atoms/cm³.

Unlike the embodiment of the invention shown in FIG. 5B, when the conductive type of the substrate 110 is n type, a p type emitter unit may be formed by using a material including impurities of a trivalent element, e.g., B₂H₆. Thereafter, an oxide including phosphor (phosphorous silicate glass, PSG) or an oxide including boron (boron silicate glass, BSG) generated as the p type impurities or the n type impurities are spread into the substrate 110, is removed through an etching process.

Then, as shown in FIG. 5C, a silicon nitride film (SiNx) is stacked on the entire surface of the emitter unit 120 by using plasma enhanced chemical vapor deposition (PECVD) and a film formation method to form the first anti-reflection film 131. In this instance, the thickness of the first anti-reflection film 131 as formed ranges from 30 nm to 50 nm.

Gases supplied to the chamber in order to form the first anti-reflection film 131 may be nitrogen gas, hydrogen gas, silane (SiH₄) gas, and ammonia (NH₃) gas. Ammonia (NH₃) need not be supplied according to circumstances or desire.

In a related art, when a lower film formed of a silicon nitride film (SiNx) having a high refractive index and an upper film formed of silicon oxide film (SiOx) having a low refractive index lower than the refractive index of the silicon nitride film are formed, the lower film has a thickness ranging from 90 nm to 100 nm and the upper film has a thickness ranging from 90 nm to 100 nm.

In general, when a film having a high refractive index is formed, it is difficult to have a uniform refractive index regardless of the position of the film and it is also difficult to form a film having the same characteristics whenever the film is formed, degrading film reproducibility. Thus, as the film having a high refractive index becomes thicker, the film characteristics become worse. However, in an embodiment of the invention, since the thickness of the first anti-reflection film 131 ranges from 30 nm to 50 nm, greatly smaller than the thickness ranging from 90 nm to 100 nm of the related art, the formation of the first anti-reflection film 131 having a high refractive index is facilitated and the characteristics of the first anti-reflection film 131 are also improved. In addition, in general, as the thickness of the anti-reflection film is increased, the quantity of light absorbed in to the anti-reflection film is increased. However, in an embodiment of the invention, since the thickness of the first anti-reflection film 131 is reduced compared with the related art, the quantity of light absorbed to the anti-reflection film 131 is reduced compared with the quantity of light absorbed to the lower anti-reflection film in the related art.

Thereafter, as shown in FIG. 5D, a silicon nitride film (SiNx) is stacked on the first anti-reflection film 131 through PECVD under a hydrogen atmosphere to form the second anti-reflection film 132. Like the first anti-reflection film 131, gases supplied into the chamber to form the second anti-reflection film 132 may be nitrogen gas, hydrogen gas, silane (SiH₄) gas, and ammonia (NH₃) gas. Again, Ammonia (NH₃) need not be used if needed or desired.

In this manner, since the first and second anti-reflection films 131 and 132 are formed of the silicon nitride film (SiNx), i.e., the same material, the first and second anti-reflection films 131 and 132 are sequentially formed to have different refractive indexes and thicknesses in the single chamber. Namely, since the same type of material is jetted or supplied into the chamber to form the first and second anti-reflection films, the first and second anti-reflection films 131 and 132 are sequentially formed by changing the process conditions. As the content of hydrogen (H) is high, the refractive index increases, and as the content of nitrogen (N) is high, the refractive index decreases, so the supply amount of hydrogen and nitrogen is controlled according to the refractive index of the first and second anti-reflection films 131 and 132, and the processing time is controlled according to the thickness of the first and second anti-reflection films 131 and 132. In this instance, as the supply amount of hydrogen (H) is high, a defect such as dangling bond by silicon (Si) and hydrogen (H) is reduced, improving the passivation effect. Thus, in an embodiment of the invention, since the refractive index of the first anti-reflection film 131 in contact with the emitter unit 120 is greater than the refractive index of the second anti-reflection film 132, namely, since the content of hydrogen of the first anti-reflection film 131 is higher than the content of hydrogen of the second anti-reflection film 132, the passivation effect can be improved by virtue of the first anti-reflection film 131.

When the first and second anti-reflection films are formed by using different materials in a single chamber, after the first anti-reflection film is formed, the environment or conditions of the chamber must be changed to form the second anti-reflection film. Otherwise, when the first and second anti-reflection films are formed by using two different chambers, the number of the chambers is increased to increase the fabrication cost, and since the substrate must be moved to the corresponding chambers, the fabrication time is lengthened.

In comparison, however, in an embodiment of the invention, since the first and second anti-reflection films 131 and 132 are made of the same material, there is no need to move the chamber or change the environment or conditions of the chamber, and the first and second anti-reflection films can be sequentially formed, so the fabrication time of the solar cell 1 can be shortened and the fabrication process of the solar cell 1 can be facilitated.

Next, as shown in FIG. 5e, a front electrode unit paste including silver (Ag) is applied to a desired region by using a screen printing method and dried at a temperature of 170° C., for example, thereby forming a front electrode unit pattern 40. In this instance, the front electrode unit pattern 40 includes a first electrode pattern and a first electrode charge collector pattern.

The front electrode unit paste may include, instead of silver (Ag), at least one from a group consisting of nickel (Ni), copper (Cu), aluminum (Al), tin (Sn), zinc (Zn), indium (In), titanium (Ti), gold (Au) and a combination thereof.

Next, as shown in FIG. 5f, after a rear electrode paste including aluminum (Al) is applied and dried to the corresponding parts of the rear surface of the substrate 110 by using a screen printing method, a rear electrode pattern 50 is formed.

The rear electrode unit paste may include, instead of aluminum (Al), at least one from a group consisting of nickel (Ni), copper (Cu), silver (Ag), tin (Sn), zinc (Zn), indium (In), titanium (Ti), gold (Au) and a combination thereof.

The order of forming the first electrode pattern 40 and the rear electrode pattern 50 may be changed.

Next, the substrate 110 equipped with the front electrode unit pattern 40 and the rear electrode pattern 50 undergoes a firing process at a temperature of about 750° C. to 800° C., for example, forming a plurality of first electrodes 141, a plurality of first electrode charge collectors 142, a rear electrode 151, and a back surface field region 171.

In other words, when a heat treatment is applied, plumbum (lead) (Pb) contained in the first electrode pattern 40 helps the first electrode pattern 40 penetrate the first and the second anti-reflection layer (131, 132) around the contact area. According to the above, the plurality of first electrodes 141 and the plurality of first electrode charge collectors 142 contacting with the emitter unit 120 are formed to complete the front electrode unit 140. At this time, the first electrode pattern of the front electrode unit pattern 40 becomes the plurality of first electrodes 141 and a first electrode charge collector pattern of the front electrode pattern 40 becomes the plurality of first electrode charge collectors.

The rear electrode 151 connected electrically and physically to the substrate 110 is formed by the heat treatment, and aluminum (Al) contained in the rear electrode 151 is diffused into the substrate 110 contacting the rear electrode 151, forming the back surface field region 171 between the rear electrode 151 and the substrate 110.

At this point, aluminum (Al) is driven in to the emitter unit 120 disposed in the rear surface of the substrate 110 to overtake the emitter unit 120 disposed in the rear surface of the substrate 110, so that the back surface field region 171 is formed at the rear surface of the substrate 110. The back surface field region 171 has the same conductive type (e.g., a p-type) as the substrate 110 and a density of impurities of the back surface field region 171 is higher than that of the substrate 110, so as for the back surface field region 171 to have a p⁺-type.

Next, an edge isolation is carried out by using laser beams to remove the emitter unit 120 formed in the sides of the substrate 110. Thereby, the emitter unit 120 formed in the front surface of the substrate 110 and the emitter unit 120 formed in the rear surface of the substrate 110 are separated electrically, thereby completing the solar cell 1 (FIG. 1 and FIG. 2).

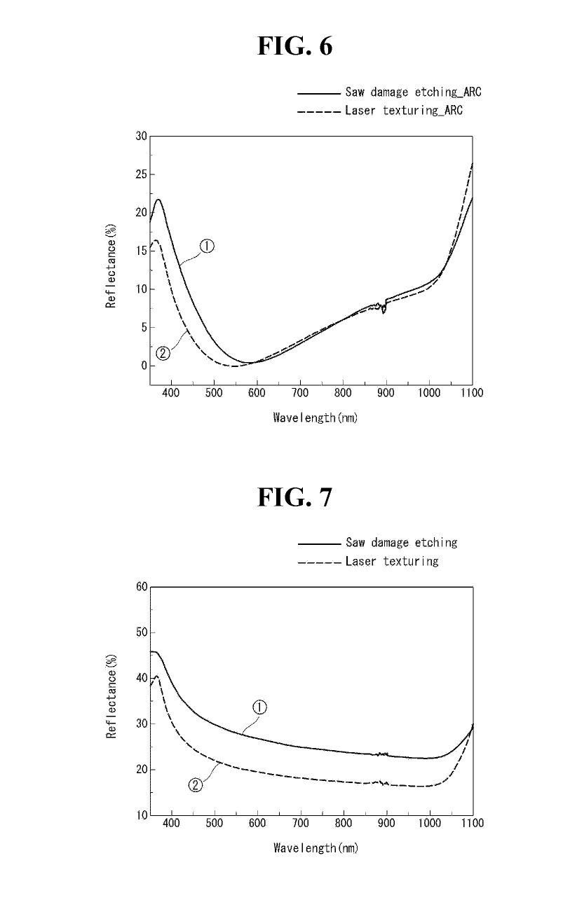

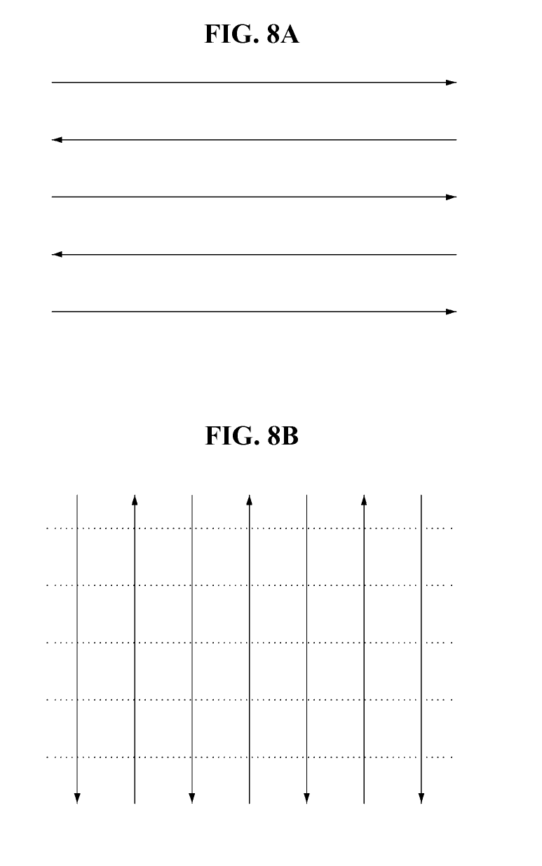

As described above, given the substrate 110 that is laser-textured to have depressions 190, and having the first and second anti-reflection films 131 and 132 formed with the same material, the anti-reflection efficiency achieved in such a substrate will be described with reference to FIGS. 6 and 7. In embodiments of the invention described with respect to FIGS. 6 and 7, the substrate 110 may have depressions 190 that are arranged such that three adjacent depressions 190 are disposed in a triangular shape as is shown in FIG. 3B, and may have the first and second anti-reflection films 131 and 132 formed with the same material, though not required.

FIG. 6 is a graph showing reflectance of light with respect to wavelength of light after performing texturing but before forming an anti-reflection unit according to a comparative example and an embodiment of the invention, and FIG. 7 is a graph showing reflectance of light with respect to wavelength of light after performing texturing and after forming first and second anti-reflection films according to a comparative example and an embodiment of the invention;

In the graphs of FIGS. 6 and 7, a curved line \textcircled{1} denotes the reflectance of light with respect to wavelength of light after the polycrystalline silicon substrate was subjected to surface processing or texturing to remove the saw damage formed in the slicing process through wet etching according to a comparative example, and a curved line \textcircled{2} denotes the reflectance of light with respect to wavelength of light after the plurality of depressions were formed by using a laser and then textured according to an embodiment of the invention.

Compared with the graph of FIG. 6, FIG. 7 is a graph of the reflectance of light with respect to the wavelength of light after the anti-reflection unit including the first and second anti-reflection films was formed on the emitter unit 120. In this instance, the refractive index of the second anti-reflection film was 1.8, and that of the first anti-reflection film was 2.3.

Based on the graph of FIG. 6, in comparative example \textcircled{1}, an average reflectance of the entire wavelength bands of light was about 30%. In comparison, in embodiment \textcircled{2}, an average reflectance of the entire wavelength bands of light was about 19%. Based on the graph of FIG. 7, in comparative example \textcircled{1}, an average reflectance of the entire wavelength bands of light was about 6.5%. In comparison, in embodiment \textcircled{2}, an average reflectance of the entire wavelength bands of light was about 5.8%.

In this manner, it is noted that when the laser texturing is performed according to the embodiment of the invention, the reflectance of light is reduced.

Also, in comparison of FIGS. 6 and 7, it is noted that, after the laser texturing is performed according to the embodiment of the invention, when the refractive index of the second anti-reflection film is 2.5 and that of the first anti-reflection film is 1.8, the reflectance of light is significantly reduced.

Also, as shown in FIG. 7, it is noted that when the wavelength of light is a short or shorter wavelength of about 700 nm or lower, the reflectance of light is significantly reduced. Thus, it can be noted that the anti-reflection unit 130 according to the embodiment of the invention is effective for reducing or preventing reflection with respect to light of a short or shorter wavelength compared with light of a long or longer wavelength.

In general, the distance by which a minority carrier generated by the long wavelength absorbed by the substrate 110 moves toward the front electrode unit 140 (namely, the bulk life time of the minority carrier) is much longer than the distance by which the minority carrier generated by the short wavelength of light absorbed by the substrate 110 (referred to as a ‘short wavelength minority carrier’, hereinafter) moves toward the front electrode unit 140.

When the solar cell 1 is fabricated by using the substrate 110 having the purity level of 5N or lower fabricated through the smelting method, since the bulk life time of the minority carrier (e.g., electrons) is as short as about 0.1 μs to 2 μs, a large amount of long wavelength minority carriers become extinct midway, rather than being normally transferred to the front electrode unit 140, while most short wavelength minority carriers are transferred to the front electrode unit 140 so as to be normally output. As a result, when the solar cell is fabricated by using the substrate 110 having the lower purity level than that of the substrate fabricated through the CVD, the improvement of the absorption efficiency of short wavelength light, rather than the absorption efficiency of long wavelength light, greatly affect the efficiency of the solar cell. Thus, the use of the anti-reflection unit 130 according to embodiments of the invention improves the anti-reflection effect with respect to the short wavelength light compared with the long wavelength light, and accordingly, it is more effective for the solar cell using the substrate having the short bulk life time and the purity level of 5N or lower, or the metallurgical grade silicon substrate.

The example embodiments of the invention have been described with reference to the accompanying drawings, and it will be apparent to those skilled in the art that various modifications and variations can be made in the invention without departing from the scope of the invention. Thus, it is intended that any future modifications of the embodiments of the invention will come within the scope of the appended claims and their equivalents.

What is claimed is:

1. A solar cell comprising:
a substrate having a first conductive type;
an emitter unit having a second conductive type, which is the opposite of the first conductive type, and forming a p-n junction with the substrate;
an anti-reflection unit positioned on the emitter unit and including a first anti-reflection film having a first refractive index and a second anti-reflection film having a second refractive index different from the first refractive index;
a first electrode connected to the emitter unit; and
a second electrode connected to the substrate,
wherein a plurality of depressions are formed on at least one surface of the substrate, a depth of each of the plurality of depressions is ⅓ to 1 times a distance between centers of at least two immediately adjacent depressions, and a width of each of the plurality of depressions is 1 to 3 times the depth of each of the plurality of depressions.

2. The solar cell of claim 1, wherein the plurality of depressions are formed such that their centers are aligned in a column direction and in a row direction.

3. The solar cell of claim 1, wherein the plurality of depressions are formed such that their centers are not aligned in at least one of a column direction and a row direction.

4. The solar cell of claim 1, wherein the depth of each of the plurality of depressions ranges from 10 μm to 70 μm.

5. The solar cell of claim 4, wherein the depth of each of the plurality of depressions ranges from 30 μm to 70 μm.

6. The solar cell of claim 1, wherein the distance between the centers of the at least two immediately adjacent depressions ranges from 30 μm to 70 μm.

7. The solar cell of claim 1, wherein the width of each of the plurality of depressions ranges from 30 μm to 70 μm.

8. The solar cell of claim 1, wherein a planar shape of each of the plurality of depressions is one of a circular shape, an oval shape, and a polygonal shape.

9. The solar cell of claim 1, wherein a sectional shape of each of the plurality of depressions is one of a semi-circular shape and a semi-oval shape.

10. The solar cell of claim 1, wherein the first anti-reflection film is made of the same material as that of the second anti-reflection film.

11. The solar cell of claim 10, wherein the same material is silicon nitride.

12. The solar cell of claim 11, wherein the first refractive index is greater than the second refractive index.

13. The solar cell of claim 12, wherein the first refractive index ranges from 2.3 to 2.9, and the second refractive index ranges from 1.7 to 2.2.

14. A method for fabricating a solar cell, the method comprising:
forming a plurality of depressions by irradiating a laser to a substrate having a first conductive type before removing saw damage caused during a previous cutting of the substrate;
simultaneously removing the saw damage and damage caused by laser irradiation by performing wet etching using an etchant after the laser irradiation;
forming an emitter unit having a second conductive type, which is the opposite of the first conductive type, on the substrate with the plurality of depressions formed thereon; and
forming a first electrode electrically connected to the emitter unit and a second electrode electrically connected to the substrate.

15. The method of claim 14, wherein the plurality of depressions are formed such that a depth of each of the plurality of depressions is ⅓ to 1 times a distance between centers of at least two immediately adjacent depressions.

16. The method of claim 14, wherein the plurality of depressions are formed such that a width of each of the plurality of depressions is 1 to 3 times the depth of each of the plurality of depressions.

17. The method of claim 14, wherein the etchant is any one of a nitric acid, a hydrofluoric acid, an acetic acid, and a mixture solution thereof.

18. The method of claim 14, wherein a thickness of a portion removed by the wet etching ranges from 3 μm to 5.5 μm.

19. The method of claim 14, wherein the forming of the plurality of depressions comprises:
performing linear laser processing in a first direction; and
performing linear laser processing in a second direction different from the first direction,
wherein the plurality of depressions are formed at crossings of regions where a laser has been irradiated in the first direction and regions where the laser has been irradiated in the second direction.

20. The method of claim 19, wherein the second direction is perpendicular to the first direction.

21. The method of claim 19, wherein the second direction crosses the first direction at an angle ranging from 40° to 80°.

22. The method of claim 14, wherein, in forming the plurality of depressions, the plurality of depressions are formed through a spot laser processing.

23. The method of claim 14, wherein, in forming the plurality of depressions, a depth of each of the plurality of depressions and a distance between centers of at least two adjacent depressions are adjusted by adjusting at least one of a speed and a frequency of the laser.

24. The method of claim 14, wherein the substrate is a polycrystalline silicon substrate.

25. The method of claim 14, further comprising:
forming an anti-reflection unit by forming a first anti-reflection film having a first refractive index on the emitter unit and forming a second anti-reflection film having a second refractive index on the first anti-reflection film, the second refractive index being smaller than the first refractive index.

26. The method of claim 25, wherein the first refractive index ranges from 2.3 to 2.9, and the second refractive index ranges from 1.7 to 2.2.

27. The method of claim 25, wherein the first anti-reflection film and the second anti-reflection film are made of the same material.

28. The method of claim 27, wherein the same materials is silicon nitride.

29. The method of claim 25, wherein, in forming the anti-reflection unit, the first and second anti-reflection films are formed in a single chamber.

30. The method of claim 25, wherein the forming of the first and second electrodes comprises:
printing a first paste on the anti-reflection unit to form a first electrode pattern;
printing a second paste on the substrate to form a second electrode pattern; and
thermally treating the substrate having the first and second electrode patterns to form the respective first and second electrodes.
